(19) United States
(12) Patent Application Publication
(10) Pub. No.: US 2011/0174220 A1
(43) Pub. Date: Jul. 21, 2011

(54) Device for Plasma-Assisted Coating of the Inner Side of Tubular Components

(75) Inventor: Stefan Laure, Stuttgart (DE)

(73) Assignee: DR. LAURE PLASMATECHNOLOGIE GMBH, Stuttgart (DE)

(21) Appl. No.: 13/055,618

(22) PCT Filed: Jul. 27, 2009
(86) PCT No.: PCT/DE2009/001041

§ 371 Date: Jan. 24, 2011

(30) Foreign Application Priority Data
Jul. 25, 2008 (DE) 10 2008 035 019.2
Jul. 26, 2008 (DE) 10 2008 034 899.6

(51) Int. Cl. C23C 16/458; C23C 16/50

(52) U.S. Cl. 118/723 R

(57) ABSTRACT

A device for plasma-assisted coating the inner side of tubular components by a high frequency magnetic field. At least two receiving bodies accommodating a tubular component by the ends, supporting and sealing the inside of the tubular component, an inflatable seal on the receiving body that is arranged about the outer side and/or the front side of a tubular component, the seal sealing the transition between the receiving body and the tubular component in relation to the surroundings, a high frequency circuit for producing a high frequency magnetic field, a coil of the high frequency circuit; the windings being coaxial to the longitudinal axis of said device. The longitudinal axis is a straight line extending through both receiving bodies, and a drive for the coil and/or the receiving body, the drive displacing the coil in relation to the receiving bodies or the receiving body in relation to the coil.

### SUMMARY

Proposed is an apparatus plasma-assisted coating of the inner side of tubular components with a high-frequency magnetic field.

Devices for plasma-assisted coating of the inner and outer side of tubular components are known from DE 199 59 845 A1 and DE 103 53 540 A1. With these the tubular component or the casing surrounding the component is closed at the open ends by flanges, and the interior of the tubular component or that of the interval between the component and casing is evacuated. For this purpose one or several vacuum pumps are attached to at least one of the two flanges. In addition the device has a high frequency resonant circuit. This is furnished with a coil which is wrapped around the tubular component. The winding of the coil runs coaxially to the component on its external side. A plasma is produced in the tubular component by the high frequency magnetic field of the coil. A coating material introduced into the tubular component is transferred by a plasma-assisted chemical reaction. The product of the reaction is deposited as a coating on the tubular component. By moving the coil relative to the tubular component or the component relative to the coil, the coating of the entire length of the component is achieved.

The tubular components to be coated often contain uneven areas on the surface and irregularities with regard to the cross section vertical to the longitudinal axis. This is especially the case with components made of glass. Even when these inaccuracies are in the area of the pre-determined production tolerance, the installation of this type of tubular component into common devices becomes difficult or impossible. The flanges of common devices show a fitted receptacle on the cross-section of the components and a seal arranged on the receptacle. An inaccuracy of the tubular component can result in it not fitting the receptacle of the flanges. Moreover an imprecision in the tubular component can have the consequence that, although it can be inserted into the receptacle, yet there is no sufficient sealing achieved by the seal. In this case, even with a high pumping output, the pressure necessary for the coating of the component is not reached. The prevailing pressure in the interior of the tubular component has an enormous effect on the quality of the coating deposited by the plasma. Reaching the pre-determined final pressure for a coating is of crucial importance for the quality of the coating.

It is the object of the invention to provide a device for plasma-assisted coating of the interior of tubular components by means of a high-frequency magnetic field, the device enabling the mounting, holding, positioning and evacuating even of components afflicted with inaccuracies with regard to the form.

This problem is solved by a device with the characteristics of claim 1. The device is characterized by being furnished with at least two receptacle bodies which are put on the ends of a tubular component, stay there and seal the interior against the environment. On the receptacle body there is at least one inflatable seal arranged, which, while inflated, forms a seal of the transition between the receptacle body and the tubular component against the environment. Thus the inflated or expanded seal is positioned on the exterior and/or front of the tubular component and seals off a space between the tubular component and the receptacle body. While inflated it forms a barrier against unintentional mass transfer between the interior of the tubular component and the environment. By expanding it, the seal will fit areas of inaccuracy, irregularity or unevenness of the tubular component and fills out the space between the receptacle body and the component. In the non-expanded status the cross section of the seal is reduced. In this position it frees up the space between itself and the receptacle body, so that a tubular component can be installed into the device or removed simply, quickly and without any damage.

Both receptacle bodies are fitted on the ends of the tubular component during installation and positioned there. Each of the two receptacle bodies has a surface area which makes contact with an end of the tubular component. Thus it can, for example, be a matter of a tubular section of a receptacle element, where the tubular component is positioned on the outside with its interior. Over the surface area the two receptacle bodies accept the weight-force of tubular component and hold the component in its position. Based on its intense spatial expansion the seal presses the tubular component onto the receptacle body and, in addition to sealing, takes care of stabilizing the component in its position on the receptacle bodies. The combination of the receptacle bodies and the inflatable seal results not only in a better seal but also in a better fitting of the tubular component.

The inflatable seal has at least one hollow space. This space is connected to a supply line and delivery tube of a medium. By feeding a medium into the hollow area, the seal is expanded. By withdrawal of the medium out of the hollow space, the inflatable seal contracts.

Thanks to the improved seal of the transition between tubular components and receptacle bodies compared to common devices, a significantly lower final pressure is reached by the same output of a vacuum pump attached to at least one receptacle body. Moreover a pre-determined final pressure is reached by a lower pumping output than with common devices. The time necessary after the installation of a tubular component into a receptacle body until a pre-determined final pressure is reached is substantially shorter than with common devices, which results in a reduced time for the whole process. Thanks to a reliable reaching of a pre-determined final pressure for tubular components with areas of inaccuracy within production tolerance, a high-quality and reproducible coating is achieved.

To obtain a plasma-assisted deposit of coating along the entire tubular component, the coil with its windings surrounding the component and the component itself are moved relative to each other. The speed of this movement can be controlled. In this way the buildup of the coating can be influenced.

Tubular components can be coated with the device when they have both ends open, one end open and one closed, or both ends closed. When components have one or two sides open the coating material can be applied via a receptacle body into the interior of the component. When components have both ends closed, the coating material must be applied to the component before it is closed.

According to an advantageous embodiment of the invention, the receptacle bodies are arranged movably in opposite directions. The effect of moving them is to increase or decrease the distance between the receptacle bodies. This allows for the installation and removal of a tubular component. For installation, the receptacle bodies are moved apart to a maximum distance between them. Then the component is inserted between the receptacle bodies and the receptacle bodies are moved back together until they touch the tubular component. A drive mechanism can be provided to move the receptacle bodies. The process can be automated. It is advantageous to provide a sensor for this which detects contact between the receptacle body and the component. As soon as contact is determined, the mechanism shuts off. If both receptacle bodies are brought into position to the component, the component is held in place by the receptacle bodies. Next the inflatable seal is expanded around the component to seal it against its environment. Then the interior of the tubular component is evacuated by the vacuum pumps to the pre-determined final pressure. When the pre-determined final pressure is reached, the plasma is ignited and the coating material is introduced into the component to apply the coating. After the coating process is completed, the component is ventilated and the expandable seal is returned to its unexpanded original state, and the receptacle bodies are removed from the component. Then the component can be removed from the device. The device is ready for the installation of the next component. Based on the variable distance between the receptacle bodies, tubular components of different lengths can be inserted between the receptacle bodies and coated with the device.

According to a further advantageous embodiment of the invention, the device is furnished with support fittings in addition to the receptacle bodies. The support fittings form a contact area for the tubular component from underneath. They make for additional support between receptacle bodies especially with long components. Furthermore they facilitate the installation of a tubular component. The receptacle bodies can be moved so far apart from each other that they do not touch the component during installation. The component is placed upon the support fittings, and the receptacle bodies are moved toward the component, whereby their distance is reduced, until they hold the component. The procedure with the demounting of the component proceeds accordingly. So the component must only be placed on the support fittings just before the coating and removed from the support fittings after the completion of the coating. All other steps can run automatically. This facilitates the coating process. No special challenges are imposed on the user. Reproducibility is increased.

According to a further advantageous embodiment of the invention, the support fittings are provided with a U-shaped bracket. This bracket is open at the upper end. If at least two such brackets are provided, the component is held firmly in place.

According to a further advantageous embodiment of the invention, the support fittings have adjustable heights. They can thus be fitted to different components with varying diameters.

According to a further advantageous embodiment of the invention, the inflatable seal in expanded position appears with an expansion in a radial direction with respect to the longitudinal axis of the receptacle bodies. They thus press externally against the component which can be held and supported from the interior by the receptacle bodies.

According to a further advantageous embodiment of the invention, the receptacle bodies each have a tubular extension which forms a contact area for the interior of the tubular component at its end. The tubular extension and the component overlap over part of the extension or its entire length. This overlapping takes care of stabilizing of the component. The tubular extension has the additional advantage of not restricting the adjustment of the pre-determined final pressure, since it has no inward protruding elements that could negatively affect the current. The tubular extension is especially effective in conjunction with an inflatable, expandable radial seal facing toward the interior. The seal presses the component in expanded position on the tubular extension.

According to a further advantageous embodiment of the invention, the tubular extension forms a boundary to the cylindrical empty space on its inner side. The wall thickness of the tubular extension is thus smaller at the end facing toward the other receptacle body than at the end facing away from the other receptacle body. This facilitates the placing of the component on the receptacle body or vice versa, since the outside diameter of the tubular extension is smaller on the side facing toward the other receptacle body.

According to a further advantageous embodiment of the invention, the receptacle bodies are furnished with a radial section facing outwards. This forms a stop position for the face side of the tubular component.

According to a further advantageous embodiment of the invention, the radial section facing outwards is furnished with a depression. In this depression a cushioning element of elastic material is placed. The cushioning element is especially more elastic than the receptacle bodies. This prevents any damage by a tubular component to the receptacle bodies.

According to a further advantageous embodiment of the invention, the radial section facing outward is furnished with a connector to conduct or remove a medium to inflate the inflatable seal. This can be compressed air, for example.

According to a further advantageous embodiment of the invention, the inflatable seal is held onto the receptacle body by a support ring. The support ring, together with the receptacle body and possibly the component, forms a boundary for the space available for the expansion of the elastic seal. Moreover it prevents the expandable seal from separating from the receptacle body.

According to a further advantageous embodiment of the invention, at least one of the receptacle bodies is connected to one or several pumps. With these pumps the pre-determined final pressure is adjusted in the tubular component.

According to a further advantageous embodiment of the invention, at least one of the receptacle bodies is furnished with a connector to conduct coating material and/or an assist gas into the interior of a component positioned on receptacle bodies. The coating material can be solid, liquid or gaseous. A precursor conditioning device can be provided to condition the coating material. Depending on requirements, the assist gas can be fed through the component in an axial direction or tangentially along the surface facing internally. In the case of a tangential speed component, turbulence is created. In this way the buildup of coating can be influenced.

According to a further advantageous embodiment of the invention, at least one of the receptacle bodies is furnished with a removable lance for conducting coating material into the interior of a tubular component arranged on the receptacle bodies. This lance is especially supportive with introducing and distributing coating material in the case of tubular components which are closed on one side.

Other advantages and successful configurations of the invention can be seen from the following description, drawings and claims.

### DRAWING

In the drawing an embodiment of the invention is represented. It shows:

FIG. 1 Apparatus for plasma-assisted coating of the interior of tubular components by means of a high frequency magnetic field with a closed flap gate, in a perspective view,

FIG. 2 Apparatus as in FIG. 1 with open flap gate,

FIG. 3 Apparatus as in FIG. 2 as viewed from the front,

FIG. 4 Section from FIG. 3 with the tubular component, the receptacle bodies, the support fixtures and the coil,

FIG. 5 Receptacle body of the apparatus according to FIG. 1 in lengthwise section without tubular component and with expandable seal in initial position,

FIG. 6 Receptacle body according to FIG. 5 with tubular component, and

FIG. 7 Receptacle body according to FIG. 6 with inflatable seal in expanded position.

### DETAILED DESCRIPTION

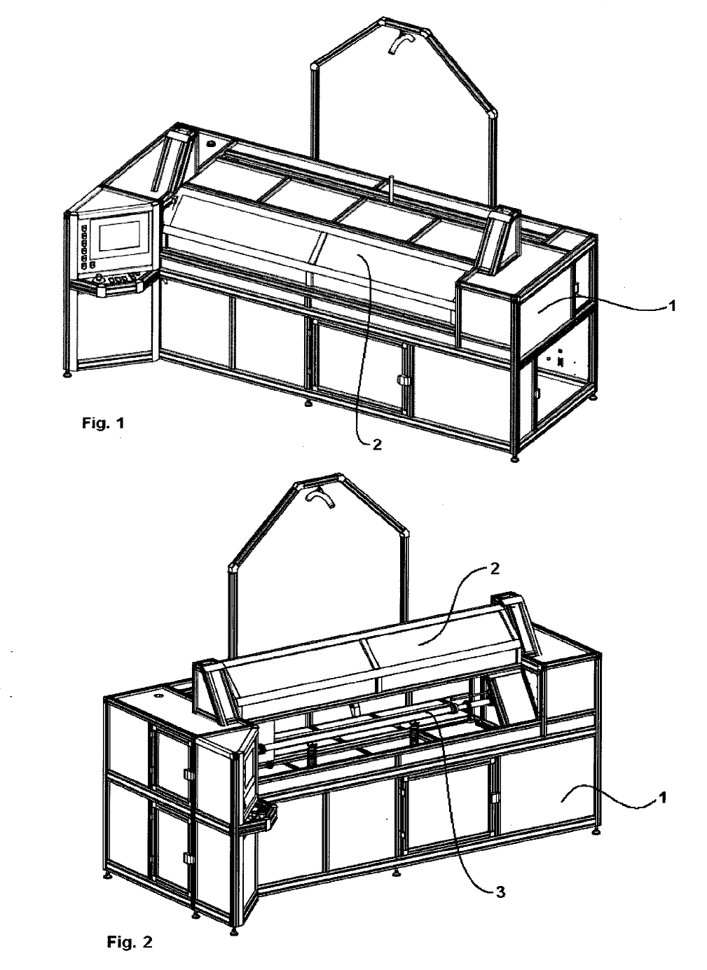

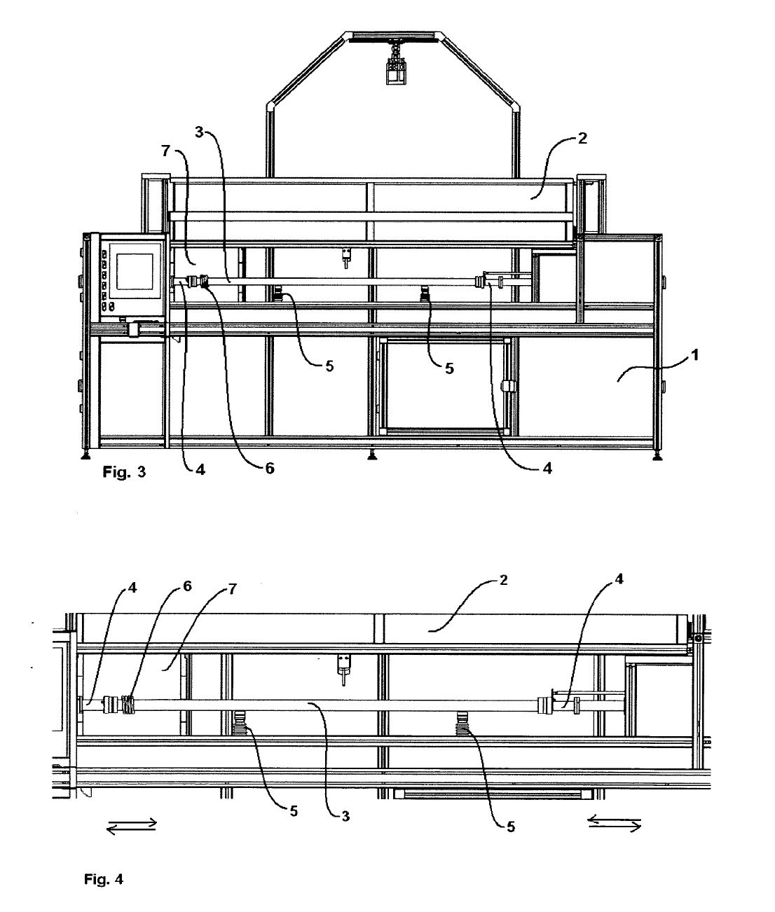

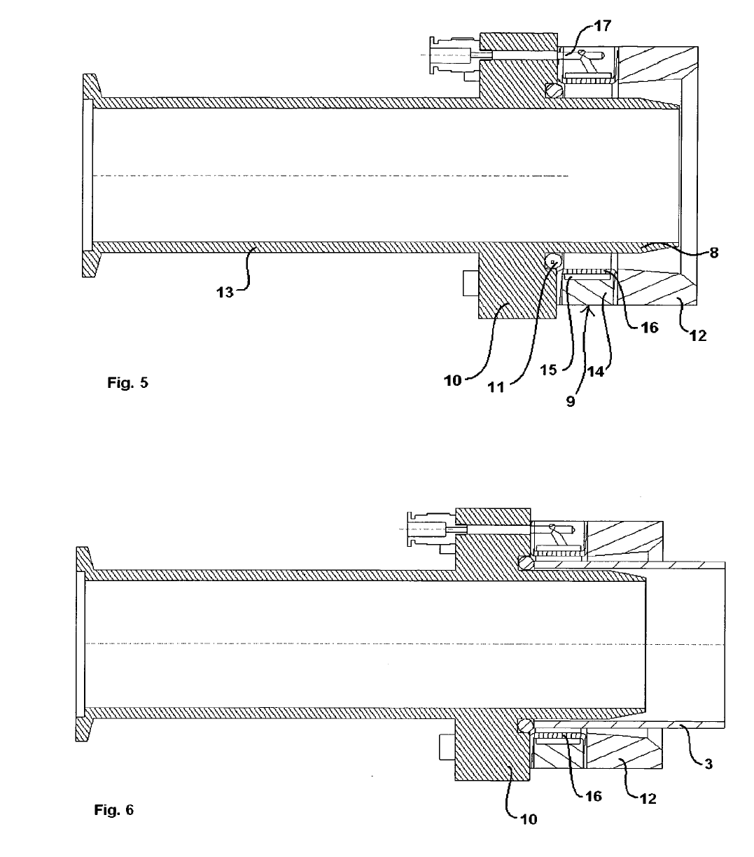

In FIGS. 1 to 4 an apparatus for plasma-assisted coating of the interior of tubular components by means of a high frequency magnetic field is depicted in various views. FIG. 1 shows the apparatus with completely closed housing 1. In FIGS. 2, 3 and 4 a flap gate 2 on housing 1 is open which closes off the area in which a tubular component 3 is arranged for the coating process. In order to hold component 1 and to seal it from its environment, receptacle bodies 4 are provided on the apparatus. These hold the component at both its ends. For installation and removal of the tubular component, the receptacle bodies 4 are moved in the direction shown by the arrows in FIG. 4. In addition the component is held by the two support fittings 5. While the two receptacle bodies 4 hold the component 3 at the side on its ends, the two support fittings 5 support the component from underneath. The component 3 held by the receptacle bodies 4 and the support fittings 5 is aligned horizontally. In the lower part of the housing 1 there are arranged vacuum pumps, a controlling device and a preparation device for the coating material or a precursor. Because the housing is closed, they are not visible in the drawing. Moreover there is a drive mechanism arranged in the housing to move the receptacle bodies 4 in the housing. This is likewise hidden by the closed housing and therefore not visible in the drawing.

In addition the apparatus is furnished with a high frequency resonant circuit, to which a coil 6 belongs. The tubular component runs within the windings of coil 6. A straight line connecting the two receptacle bodies along their symmetrical axis with each other coincides with the longitudinal axis of tubular component 3 and the longitudinal axis of the windings of coil 6. This straight line is defined as the longitudinal axis of the apparatus. It is not depicted in the drawing. The other components of the resonant circuit are arranged in the housing part 7. Coil 6 is firmly connected to housing part 7. In order to coat the interior of tubular component 3, coil 6 together with housing part 7 are pushed together parallel to the tubular component, so that coil 6 covers the entire length of the component in a timely manner. In the drawing according to FIGS. 2, 3 and 4, coil 6 and housing part 7 are located on the right side.

Coil 6 can be wrapped cylindrically or conically. In addition it can contain at least one winding in the opposite direction. Furthermore the coil can be adapted to the diameter of tubular component 3. The frequency of the high frequency resonant circuit, the formation of the plasma and the layering of the coating can be influenced by the choice and configuration of coil 6.

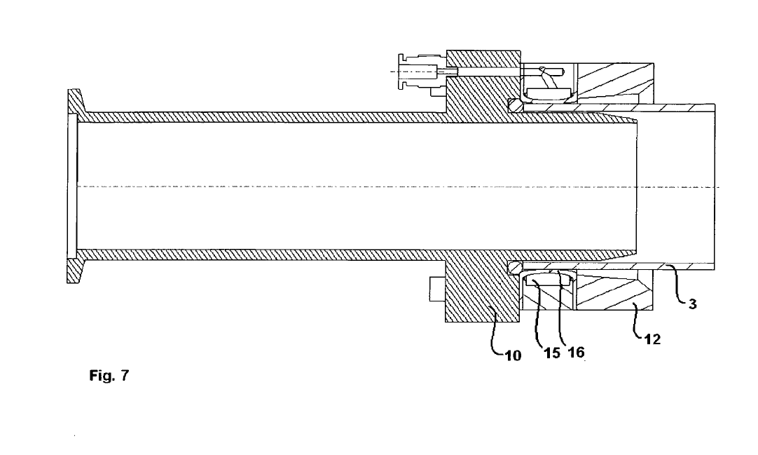

In FIGS. 5, 6 and 7 a receptacle body 4 of the apparatus is depicted in longitudinal cross-section based on FIG. 1. The receptacle body has a tubular extension 8, an inflatable seal 9, a radial section sticking outward 10, a cushioning element 11, a support ring 12 and a connecting piece 13. Tubular component 3 is pushed over tubular extension 8. This is visible in FIGS. 6 and 7. The outer diameter of tubular extension 8 is smaller than the inner diameter of tubular component 3. The front part of tubular component 3 pushes against cushioning element 11, which is arranged in a depression of the radial section sticking out 10. The inflatable seal is held between the radial section sticking outward 10 and the support ring 12. It has a base body 14, a hollow space 15 and an elastic element 16. Compressed air is introduced and pumped out in the hollow space 15 via a conduit 17 running in base body 14 and the radial section sticking out 10. One of the receptacle bodies 4 is linked with connecting piece 13 to the system of vacuum pumps. The other receptacle body 4 is linked with connecting piece 13 to the preparation device for the coating material or a precursor. The connecting pieces are also visible in the depiction according to FIG. 4.

FIG. 7 shows the receptacle body 4 with tubular component 3 and expanded inflatable seal 9. In the drawing only the end of component 3 facing receptacle body 4 is visible. FIG. 7 shows that the hollow space 15 is enlarged because of a medium flowing through conduit 17 and the elastic element pressed against tubular component 3. Thus the transition between receptacle body 4 and component 3 is sealed off. From the drawing it is visible that a sealing also occurs when a space exists between tubular extension 8 of receptacle body 4 and component 3.

The apparatus depicted in FIGS. 1 to 7 is especially suited for coating glass tubes with silicon dioxide for solar thermal purposes. Coating reduces the reflection of incidental sunlight and increases optical transmission. In the coating process an alcohol containing silicon is used in liquid form, which exists as a vapor following preparation and is added to a glass tube to be coated while adding oxygen. In plasma the alcohol containing silicon and the oxygen become silicon dioxide, carbon dioxide and water. Silicon dioxide separates as a coating on the interior wall of the tube. Water and excess oxygen are pumped out of the glass tube by a system of vacuum pumps.

All characteristics can be essential to the invention, both individually and in any combination with each other.

Table of Parts

1 Housing

2 Flap gate

3 Tubular component

4 Receptacle body

5 Support fitting

6 Coil

7 Housing part

8 Tubular extension

9 Inflatable seal

10 Radial section sticking outward

11 Cushioning element

12 Support ring

13 Connecting piece

14 Base body

15 Hollow space

16 Elastic element

17 Conduit

1. Apparatus for plasma-assisted coating of an inner side of a tubular component with a high frequency magnetic field, comprising:
at least two receptacle bodies (4) which receive the tubular component (3) at its ends, hold it, and seal an interior of the tubular component,
with an inflatable seal (9) on the receptacle bodies (4), the inflatable seal (9) positioned around an outer side and/or a front of the tubular component (3), which in an expanded position forms a seal of a transition between the receptacle bodies (4) and the tubular component (3),
with a high frequency resonant circuit to produce a high frequency magnetic field,
with a coil (6) of the high frequency resonant circuit, of which a winding is aligned coaxially with a longitudinal axis of the apparatus, whereby the longitudinal axis is pre-determined by a straight line that runs through both receptacle bodies (4),
with a drive mechanism for the coil (6) and/or the receptacle bodies (4), which moves the coil (6) relative to the receptacle bodies (4) or the receptacle bodies (4) relative to the coil (6).

2. Apparatus according to claim 1, characterized in that the receptacle bodies (4) are movable in opposite directions.

3. Apparatus according to claims 1, characterized in that it is furnished with support fittings (5) in addition to receptacle bodies (4),
which form a contact area for tubular component (3).

4. Apparatus according to claim 3, characterized in that support fittings (5) are provided with a U-shaped bracket.

5. Apparatus according to claim 3, characterized in that the support fittings (5) have adjustable heights.

6. Apparatus according to claim 1, characterized in that the inflatable seal (9) in the expanded position extends in a radial direction with respect to the longitudinal axis of the receptacle bodies (4).

7. Apparatus according to claim 1, characterized in that each of the receptacle bodies (4) has a tubular extension (8) which forms a contact area of the tubular component (3) at its end.

8. Apparatus according to claim 7, characterized in that the tubular extension (8) forms a boundary of a hollow space on its interior side, and the wall thickness of the tubular extension (8) is smaller on the end facing the other receptacle body (4) than the end facing away from the other receptacle body (4).

9. Apparatus according to claim 1, characterized in that the receptacle bodies (4) are furnished with a radial section sticking out (10), which forms a stopping point for the front of the tubular component (3).

10. Apparatus according to claim 9, characterized in that the radial section sticking out (10) is furnished with a depression, and in the depression a cushioning element (11) of an elastic material is arranged.

11. Apparatus according to claim 9, characterized in that the radial section sticking out (10) is furnished with a connector to conduct and remove a medium to inflate the inflatable seal.

12. Apparatus according to claim 1, characterized in that the inflatable seal (9) is held by a support ring on the receptacle body (4).

13. Apparatus according to claim 1, characterized in that at least one of the receptacle bodies (4) is furnished with a connection (13) to one or several pumps.

14. Apparatus according to claim 1, characterized in that at least one of the receptacle bodies (4) is furnished with a connection (13) to conduct coating material and/or an assist gas into the interior of the receptacle bodies (4) arranged onto the tubular component (3).

15. Apparatus according to claim 1, characterized in that at least one of the receptacle bodies (4) is furnished with a removable lance to conduct a coating material into the interior of the receptacle bodies (4) arranged onto the tubular component (3).
